(19) United States
(12) Patent Application Publication
(10) Pub. No.: US 2024/0069108 A1
(43) Pub. Date: Feb. 29, 2024

(54) METHOD FOR EVALUATING THE QUANTITY OF ELECTRICAL ENERGY CONSUMED BY A COMMUNICATING OBJECT

(71) Applicant: SAGEMCOM ENERGY & TELECOM SAS, Rueil Malmaison (FR)

(72) Inventors: Patrick WEBER, Rueil Malmaison (FR); Xavier FERRIERES, Rueil Malmaison (FR)

(73) Assignee: SAGEMCOM ENERGY & TELECOM SAS, Rueil Malmaison (FR)

(21) Appl. No.: 18/350,666

(22) Filed: Jul. 11, 2023

(30) Foreign Application Priority Data
Aug. 24, 2022 (FR) 2208501

(51) Int. Cl. G01R 31/367; G01R 31/382

(52) U.S. Cl. CPC G01R 31/367; G01R 31/382

(57) ABSTRACT

The present invention relates to a method and a device for evaluating the quantity of electrical energy consumed by a communicating object supplied by cell, the communicating object being able to implement a plurality of functionalities, according to the invention:
an activation of a functionality of the communicating object is detected (E30),
it is checked (E31) in a table whether an electrical-energy consumption is associated with the functionality activated,
an estimation of the quantity of electrical energy consumed by the functionality activated if an electrical-energy consumption is associated with the functionality activated is demanded (E32),
a measurement is demanded (E35) of the quantity of electrical energy consumed by the functionality activated if an electrical-energy consumption is not associated with the functionality activated.

### TECHNICAL FIELD

The invention relates to the field of communicating meters supplied by battery and relates more particularly to the field of evaluation of the quantity of electrical energy consumed by a communicating object that is the most precise possible while consuming the least electrical energy.

### PRIOR ART

As is known, the Internet of Things (IoT) is continually expanding. The Internet of Things represents the extension of the internet to things and to places in the physical world. Whereas the internet does not normally extend beyond the electronic world, the Internet of Things represents exchanges of information and data coming from devices present in the real world to the internet, such as for example for collecting water consumption readings or for the remote monitoring of environmental conditions (temperature, pressure, etc). The Internet of Things is considered to be the third evolution of the internet, termed Web 3.0. The Internet of Things has a universal character for designating connected objects with varied uses, for example in the field of e-health or home automation.

A first approach adopted for interconnecting objects, referred to as communicating objects (“IoT device”), in the context of the Internet of Things, relies on a deployment, controlled by an operator, of collecting gateways located on geographically high points. Apart from maintenance operations, these gateways are fixed and permanent. The SigFox (registered trade mark) or ThingPark (registered trade mark) networks can for example be cited with regard to this model. For example, in France, the SigFox (registered trade mark) network relies on high points of the TDF («Télédiffusion de France») transmission sites. These collecting gateways communicate with the communicating objects by means of medium- or long-range radio communication systems (e.g. the LoRa (registered trade mark) system of the company Semtech). This approach relies on a limited number of collecting gateways (difficulty in deploying new network infrastructures), as well as on a reliable and secure uplink access with one or more collecting servers.

A second approach consists of connecting communicating objects through residential gateways. Mention can for example be made of the Energy Gateway technology. A system according to the Energy Gateway technology is composed of two distinct parts: firstly a residential gateway and peripheral sensors, which are hosted at the consumer and which allow the collection of information, the transmission of this information to a collecting server, and control of the triggering of the various actions (control of the triggering of radiators or of the water heater for example); secondly, the collecting server that provides the making available of the information received and the transmission of commands for controlling triggering of various actions. This collecting server is accessible via the internet. The radio technologies used for communicating with the communicating objects according to this second approach are of relatively short range (for example of the Zigbee (registered trade mark), Bluetooth (registered trade mark) or Wi-Fi (registered trade mark) type) for serving a local collection restricted to the objects in the dwelling.

Such communicating objects typically comprise one or more sensors, and are typically supplied by cell (or batteries). One difficulty lies in preserving the service life of the cells, and more particularly in guaranteeing the operation of the essential functionalities of such communicating objects throughout the service life of the cells.

For this purpose, some communicating objects are equipped with systems for evaluating the remaining quantity of energy in the battery so as to ensure the integrity of the data stored and/or supplied by these communicating objects when the cells arrive at the end of their life.

Some systems for evaluating the quantity of remaining energy in the battery use a physical system for measuring the electrical consumption of the communicating object. These systems for measuring the consumed current or power consume energy.

Other systems for evaluating the quantity of remaining energy in the battery are software. These software systems may in some cases be imprecise.

Thus it is desirable to provide a method for evaluating the quantity of electrical energy consumed by a communicating object that is the most precise possible while consuming the least electrical energy.

### DISCLOSURE OF THE INVENTION

For this purpose, according to a first aspect, a method is proposed for evaluating the quantity of electrical energy consumed by a communicating object supplied by cell, the communicating object being able to implement a plurality of functionalities, characterised in that the method comprises the steps of:
detecting an activation of a functionality of the communicating object,
checking in a table whether an electrical-energy consumption is associated with the functionality activated,
demanding an estimation of the quantity of electrical energy consumed by the functionality activated if an electrical-energy consumption is associated with the functionality activated,
demanding a measurement of the quantity of electrical energy consumed by the functionality activated if an electrical-energy consumption is not associated with the functionality activated,

Thus the evaluation of the quantity of electrical energy consumed by a communicating object is precise while consuming a minimum of electrical energy.

According to a particular embodiment of the invention, the communicating object is a communicating fluid meter.

According to a particular embodiment of the invention, the plurality of functionalities comprises at least one functionality of display on a screen, a functionality of measuring fluid flow rate, a functionality of communication by a Bluetooth link, a functionality of communication by an optical link and a functionality of communication by a radio channel. According to a particular embodiment of the invention, if in the table an electrical-energy consumption is associated with the functionality activated, the method further comprises the steps of:
demanding a measurement of the quantity of electrical energy consumed by the functionality activated,
checking whether the estimation of the electrical-energy consumption of the functionality activated corresponds to the measurement of the electrical-energy consumption of the functionality activated,
modifying in the table the value of the electrical-energy consumption associated with the functionality if the estimation of the electrical-energy consumption of the functionality activated does not correspond to the measurement of the electrical-energy consumption of the functionality activated,

According to a particular embodiment of the invention, when the measurement of the quantity of electrical energy consumed by a functionality activated is stable over time, the measured value is associated with the functionality activated and is stored in the table. The invention also relates to a device for evaluating the quantity of electrical energy consumed by a communicating object supplied by cell, the communicating object being able to implement a plurality of functionalities, characterised in that the device comprises:
means for detecting an activation of a functionality of the communicating object,
means for checking in a table whether an electrical-energy consumption is associated with the functionality activated,
means for demanding an estimation of the quantity of electrical energy consumed by the functionality activated if an electrical-energy consumption is associated with the functionality activated,
means for demanding a measurement of the quantity of electrical energy consumed by the functionality activated if an electrical-energy consumption is not associated with the functionality activated.

According to another aspect, a computer program product is proposed, comprising program code instructions for executing the management method, when said instructions are executed by a processor.

According to another aspect, a non-transient storage medium is proposed, on which a computer program product is stored, comprising program code instructions for executing the management method, when said instructions are read from said non-transient storage medium and executed by a processor.

### BRIEF DESCRIPTION OF THE DRAWINGS

The features of the invention mentioned above, as well as others, will emerge more clearly from the reading of the following description of at least one example embodiment, said description being made in relation to the accompanying drawings, among which:

FIG. 1 illustrates schematically an example of hardware architecture of a communicating object supplied by cell;

FIG. 2 illustrates schematically an example of hardware architecture of a control unit of a communicating object; and

FIG. 3 shows an example of an algorithm for evaluating the quantity of electrical energy consumed by a communicating meter according to the present invention.

### DETAILED DISCLOSURE OF EMBODIMENTS

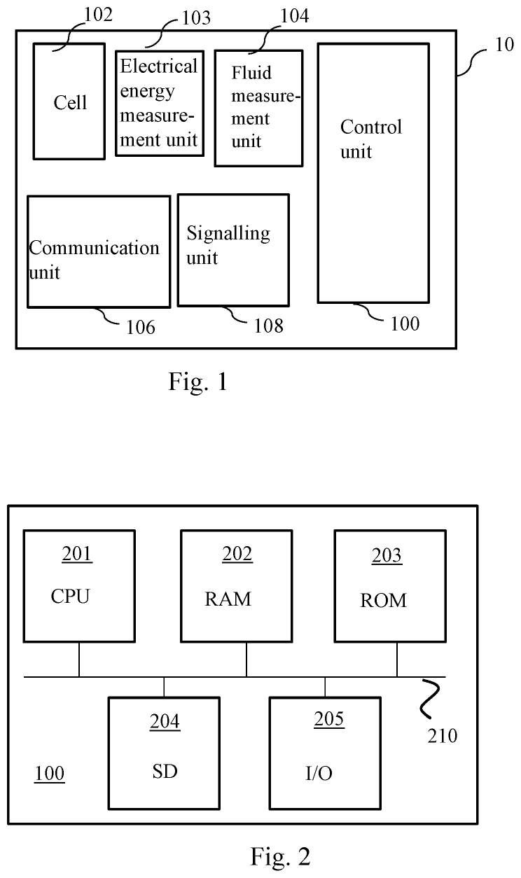

FIG. 1 illustrates schematically an example of hardware architecture of a communicating object supplied by cell.

The present invention is described in a particular embodiment where the communicating object is a fluid meter 1, i.e. adapted and configured to measure a consumption of a fluid (water, gas, etc). The present invention is also applicable to communicating objects such as sensors for temperature, pressure, humidity, etc.

The communicating object comprises a control unit 100, a cell 102, a unit 103 for measuring the electrical-energy consumption, a fluid-measurement unit 104, a communication unit 106 and a signalling unit 108.

The term ‘cell’ is must be understood as being a single cell, or a set of cells providing conjointly an autonomous source of electrical energy.

Typically, the fluid-measurement unit 104 can be adapted and configured to measure a consumption of water, or a consumption of another fluid such as gas. In this regard, the measurement unit 4 comprises known means for measuring (metrology) and monitoring a consumption of water.

The unit for measuring the electrical-energy consumption 103 consists of electronic components able to measure a current delivered by the cell 102 or an electrical power delivered by the cell 102 to the communicating object or to a part of the communicating object such as for example the communication unit 106. According to the invention, the unit for measuring the electrical-energy consumption 103 is activated or deactivated by the control unit 100.

The communication unit 106 comprises a set of communication members allowing the transmission of measurements acquired by the measuring unit 104, for example to a collecting gateway or to a residential gateway.

Typically, the communication unit 106 comprises members for communication via a telephone network, via the internet (protocols for communication on IP), via a LoRa (registered trade mark) system of the company Semtech, via a Wi-Fi (registered trade mark) system, via a system of the Zigbee (registered trade mark) type, via a system of the Bluetooth (registered trade mark) type, via a low power wide area network system (LPWAN), or via a cellular network dedicated to the Internet of Things of the NB-IOT type («Narrowband Internet of Things»), or of the LTE Cat-M («Long Term Evolution—Category Machine») type.

The signalling unit 108 comprises electronic circuitry for sending alarm signals. Typically, the signalling unit may comprise members allowing the sending of optical signals (for example light-emitting diodes). In addition, the signalling unit 108 can transmit alarm signals via the communication unit 106 to transmit the alarm signals to remote units via wireless systems as stated previously.

The control unit 10 comprises electronic circuitry for controlling and coordinating all the previously mentioned units.

Furthermore, the control unit 10 is adapted to implement a method for evaluating the quantity of electrical energy consumed by a communicating meter according to the present invention.

FIG. 2 illustrates schematically an example of hardware architecture of the control unit 100. According to this example, the control unit 100 comprises, connected by a communication bus 210: a processor or CPU (“central processing unit”) 201; a random access memory (RAM) 202; a read only memory (ROM) 203; a storage unit or a storage medium reader, such as an SD (“Secure Digital”) card reader 204; a set of interfaces 205 enabling the control unit 10 to communicate with the other elements of the hardware architecture presented above in relation to FIG. 1.

The processor 201 is capable of executing instructions loaded in the RAM 202 from the ROM 203, from an external memory, from a storage medium, or optionally from a communication network. When the control unit 100 is powered up, the processor 201 is capable of reading instructions from the RAM 202 and executing them. These instructions form a computer program causing the implementation, by the processor 201, of all or part of the evaluation method described hereinafter.

Thus all or part of the evaluation method described hereinafter can be implemented in software form by executing a set of instructions by a programmable machine, such as a DSP (“digital signal processor”), or a microcontroller. All or part of the algorithm and steps described here can also be implemented in hardware form by a machine or a dedicated component, such as an FPGA (“field-programmable gate array”), or an ASIC (“application-specific integrated circuit”).

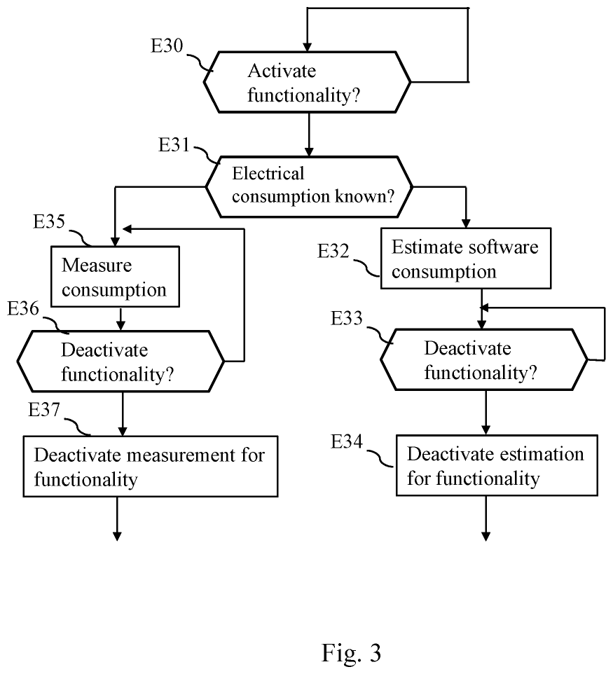

FIG. 3 shows an example of an algorithm for evaluating the quantity of electrical energy consumed by a communicating meter according to the present invention.

The present algorithm is executed by the control unit 100.

According to the invention, a table is stored in the ROM memory 203, which associates an electrical-energy consumption with at least one functionality of the communicating object. The electrical-energy consumption is for example determined from measurements of electrical-energy consumption made in the laboratory for communicating objects of the same type and/or from data supplied by the manufacturer of the electronic components used in implementing the functionality. For example, an electrical-energy consumption is associated with the functionality of display on a screen, an electrical-energy consumption is associated with the functionality of measuring the flow rate of fluid, an electrical-energy consumption is associated with the functionality of communication by a Bluetooth link, and an electrical-energy consumption is associated with the functionality of communication by an optical link.

In a particular embodiment, the table associates values of electrical-energy consumption for various temperatures with at least one functionality of the communicating object. Some functionalities such as for example a radio communication of the LTE Cat-M type are subject to large variations, for example related to dispersions in the impedance of the antenna and to communication conditions related to the environment. According to the invention, no electrical-energy consumption is associated with these functionalities. At the step E30, the control unit 100 checks whether a new functionality is activated. If a new functionality is activated, the control unit 100 passes to the step E31. At the step E31, the control unit checks whether an electrical-energy consumption is associated with the functionality activated, by interrogating the table.

If so, the control unit 100 passes to the step E32. If not, the control unit 100 passes to the step E35.

At the step E32, the control unit 100 demands an estimation of the quantity of electrical energy consumed by the functionality activated,

More precisely, the control unit 100 activates a time meter associated with the functionality activated.

At the following step E33, the control unit 100 checks whether the functionality is deactivated.

If so, the control unit 100 passes to the step E34.

At the step E34, the control unit deactivates the software estimation of the electrical-energy consumption of the functionality, stores the value of the time meter associated with the functionality activated and interrupts the time meter associated with the functionality activated.

At the step E35, the control unit 100 demands a measurement of the quantity of electrical energy consumed by the functionality activated and activates a time meter associated with the functionality activated.

The measurement of the quantity of electrical energy consumed by the functionality activated is for example made by measuring the current passing through a low-value resistor placed between the cell and the components to which the electrical energy is supplied.

The measurements of the current are stored.

It should be noted here that the measurement of the current is made for all the components of the communicating object or only for the components of the functionality activated. At the following step E36, the control unit 100 checks whether the functionality is deactivated.

If so, the control unit 100 passes to the step E37. If not, the control unit 100 returns to the step E35.

At the step E37, the control unit deactivates the measurement of the electrical-energy consumption of the functionality, stores the value of the time meter associated with the functionality activated and interrupts the time meter associated with the functionality activated.

It should be noted that, in a particular embodiment, the measurement of the electrical-energy consumption of the functionality activated and the estimation of the electrical-energy consumption of the functionality activated can be done simultaneously in a temporary manner to check whether the estimation of the electrical-energy consumption of the functionality activated corresponds to the actual electrical-energy consumption of the functionality activated and, if not, modifies the value of the electrical-energy consumption associated with the functionality.

In a particular embodiment, when the measurement of the current consumed by a functionality activated is stable over time, for example fluctuates in a range of values of +/−5%, the measured value is associated with the functionality activated and is stored in the table.

The electrical-energy capacity remaining in the cell is determined for example using the following formula: Cr=C₀−ΣᵢDᵢ*Iᵢ where Cr is the electrical-energy capacity remaining in the cell, C₀ is the initial electrical-energy capacity of the cell, Dᵢ is the value of the time meter associated with the functionality i and Iᵢ is the electrical-energy consumption value associated with the functionality i or the value of the current measured for the functionality i.

1. Method for evaluating the quantity of electrical energy consumed by a communicating object supplied by cell, the communicating object being able to implement a plurality of functionalities, wherein the method comprises the steps of:
detecting an activation of a functionality of the communicating object,
checking in a table whether an electrical-energy consumption is associated with the functionality activated,
demanding an estimation of the quantity of electrical energy consumed by the functionality activated if an electrical-energy consumption is associated with the functionality activated,
demanding a measurement of the quantity of electrical energy consumed by the functionality activated if an electrical-energy consumption is not associated with the functionality activated.

2. The method according to claim 1, wherein the communicating object is a communicating fluid meter.

3. The method according to claim 2, wherein the plurality of functionalities comprises at least one functionality of display on a screen, a functionality of measuring fluid flow rate and a functionality of communication by a radio channel.

4. The method according to, claim 1, wherein, if in the table an electrical-energy consumption is associated with the functionality activated, the method further comprises the steps of:
demanding a measurement of the quantity of electrical energy consumed by the functionality activated,
checking whether the estimation of the electrical-energy consumption of the functionality activated corresponds to the measurement of the electrical-energy consumption of the functionality activated,
modifying in the table the value of the electrical-energy consumption associated with the functionality if the estimation of the electrical-energy consumption of the functionality activated does not correspond to the measurement of the electrical-energy consumption of the functionality activated.

5. The method according to claim 2, wherein, when the measurement of the quantity of electrical energy consumed by a functionality activated is stable over time, the measured value is associated with the functionality activated and is stored in the table.

6. A device for evaluating the quantity of electrical energy consumed by a communicating object supplied by cell, the communicating object being able to implement a plurality of functionalities, wherein the device comprises:
means for detecting an activation of a functionality of the communicating object,
means for checking in a table whether an electrical-energy consumption is associated with the functionality activated,
means for demanding an estimation of the quantity of electrical energy consumed by the functionality activated if an electrical-energy consumption is associated with the functionality activated,
means for demanding a measurement of the quantity of electrical energy consumed by the functionality activated if an electrical-energy consumption is not associated with the functionality activated.

7. (canceled)

8. A non-transient storage medium on which a computer program product is stored, comprising program code instructions for executing the method according to claim 1, when the instructions are read from the non-transient storage medium and executed by a processor.
